(19) United States
(12) Patent Application Publication
(10) Pub. No.: US 2016/0240778 A1
(43) Pub. Date: Aug. 18, 2016

(54) Multi-Value Nonvolatile Organic Resistive Random Access Memory and Method for Preparing the Same

(71) Applicant: PEKING UNIVERSITY, Beijing (CN)

(72) Inventors: Yimao Cai, Beijing (CN); Yefan Liu, Beijing (CN); Yichen Fang, Beijing (CN); Zongwei Wang, Beijing (CN); Qiang Li, Beijing (CN); Muxi Yu, Beijing (CN); Yue Pan, Beijing (CN); Ru Huang, Beijing (CN)

(21) Appl. No.: 15/024,996

(22) PCT Filed: Mar. 31, 2014
(86) PCT No.: PCT/CN2014/074359

§ 371 Date: Mar. 25, 2016

(30) Foreign Application Priority Data
Feb. 11, 2014 (CN) 201410047253.4

(51) Int. Cl. H01L 45/00; G11C 13/00

(52) U.S. Cl. CPC H01L 45/14; H01L 45/122; H01L 45/1253; H01L 45/1616; G11C 13/0097

(57) ABSTRACT

Disclosed are a multi-value nonvolatile organic resistive random access memory and a method for preparing the same. The resistive random access memory comprises a top electrode, a bottom electrode and a middle functional layer located between the top electrode and the bottom electrode, the middle functional layer is at least two layers of parylene. The method comprises the steps of: growing material for the bottom electrode using physical vapor deposition method on a substrate; growing sequentially multiple layers of parylene on the bottom electrode by polymer chemical vapor deposition; defining the via for leading out the bottom electrode by lithography and etching; growing material for the top electrode on the parylene materials by using physical vapor deposition process, defining the top electrode material by lithography and lift-off, and leading out the bottom electrode.

The present application claims priority of Chinese Patent Application (No. 201410047253.4), filed on Feb. 11, 2014, which is incorporated herein by reference in its entirety.

### TECHNICAL FIELD

The invention belongs to a field of organic electronics and CMOS hybrid integrated circuit technology, and particularly refers to a structure of a multi-value nonvolatile organic resistive random access memory and a method for preparing the same.

### BACKGROUND OF THE INVENTION

In recent years, resistive random access memory has attracted considerable attention and has made great progress in the integrated circuits field. Resistive random access memory belongs to nonvolatile memory, and the current market share of a nonvolatile memory is occupied mainly by flash memory. With a further development of the integrated circuit, the resistive random access memory becomes a strong competitor of the new generation memory due to its advantages of the aspects such as scaling down and operating voltage. The basic principle of the resistive random access memory is that, a resistance of a memory structure may achieve a reversible switching between a high-resistance state (“0”) and a low-resistance state (“1”) under applied voltage or current, thereby achieving storing of data. An operation of switching the device from the high-resistance state to the low-resistance state is referred to as SET process, and an operation of switching the from the low-resistance state to the high-resistance state is referred to as RESET process. In choosing materials for the resistive random access memory, organic materials exhibit huge advantages. Organic materials have lots of varieties, simple synthesis and preparation processes, and low cost. Meanwhile, organic materials could be used to achieve transparent electronic systems such as a transparent paper (e.g. e-paper) and an electronic display (e.g. OLED), etc.

On the other hand, multi-value storage is always a remarkable research area for nonvolatile memory. Multi-value storage plays significant roles in enhancing a storage density. For the resistive random access memory, one of methods of multi-value achievement is to introduce middle-resistance states between the high-resistance state and the low-resistance state, so that each memory cell can store more than two states. In current research, according to the different characteristics of the device, the method of achieving the middle-resistance states could be classified roughly into two: 1. applying limit currents in SET processso that the SET of the device is insufficient, thereby achieving the relatively higher low-resistances; 2. applying the voltages with different magnitudes in RESET process so that the RESET process of the device is insufficient, thereby achieving the relatively lower high-resistance. However, firstly the above two methods set some requirements on an peripheral control circuit, secondly it is usually not significant in distinguishing between the different resistance states, there are considerable difficulties in practical application, and it is an important research area that how to design and achieve more practical multi-value nonvolatile memory.

### SUMMARY OF THE INVENTION

For the problems described above, the present invention proposes an organic resistive random access memory for achieving multi-value storage based on multilayer parylene and a method for preparing the same.

The technical solutions of the present invention are provided as follows:

A multi-value nonvolatile organic resistive random access memory comprises a top electrode, a bottom electrode and a middle functional layer located between the top electrode and the bottom electrode, the middle functional layer is at least two layers of parylene.

Preferably, the top electrode and the bottom electrode both use an inert electrode, preferably W electrode, and have a thickness between 200 nm and 500 nm.

Preferably, the resistive random access memory described above is based on a silicon substrate.

Preferably, a total thickness of the layers of parylene as the functional layer is between 40 nm and 80 nm, the depositions of the layers are performed multiple times separately, and there is a time of one day, between the depositions of each two layers, for exposing at the atmosphere for surface oxidation, and each layer has a thickness controlled to be between 10 nm˜20 nm.

Preferably, a polymer of the parylene is parylene-C type, parylene-N type or parylene-D type.

Meanwhile, the present invention also provides a method for preparing a multi-value nonvolatile organic resistive random access memory described above, the method comprises the steps of:
1) growing material for a bottom electrode using physical vapor deposition (PVD) process, and patterning the bottom electrode using standard lithography technology;
2) sequentially growing multiple layers of parylene on the bottom electrode by polymer chemical vapor deposition (Polymer CVD);
3) defining a via for leading out the bottom electrode by lithography and etching;
4) growing material for the top electrode on parylene using the physical vapor deposition (PVD) process, defining the top electrode by lithography and lift-off, and leading out the bottom electrode.

Preferably, the material for the top electrode and the material for the bottom electrode are W, each have a thickness between 200 nm and 500 nm, and the substrate is silicon.

Preferably, a total thickness of the layers of parylene as the functional layer is between 40 nm and 80 nm, to the depositions of the layers are performed multiple times separately, there is a time of one day, between the depositions for each two layers, for exposing at the atmosphere for surface oxidation, and each layer has a thickness controlled to be between 10 nm and 20 nm.

Preferably, in the step 2) of growing parylene by Polymer CVD process, a deposition speed is between 1 nm/min and 10 nm/min.

Preferably, a polymer of the parylene is parylene-C, parylene-N or parylene-D.

Preferably, the etching in the step 3) is RIE.

The present invention has beneficial effects as follows: without changing the basic structure of the device, a multi-value storage function with self-limiting current effect could be realized by using inert electrodes at both sides and depositing multiple layers of parylene.

### BRIEF DESCRIPTION OF THE DRAWINGS

FIG. 1 is a schematic graph illustrating the current-voltage characteristic curves during the resistive switching processes of a multi-value nonvolatile organic resistive random access memory according to the present invention;

FIG. 2 to FIG. 7 are schematic views of the devices in respective steps of a method for preparing the resistive random access memory according to an embodiment;

FIG. 8 shows a legend for FIG. 2 to FIG. 7.

### DETAILED DESCRIPTION OF THE EMBODIMENTS

Hereinafter, the present invention will be further described with reference to the specific embodiments in conjunction with the accompany drawings.

The present invention proposes a new resistive random access memory structure to achieve a multi-value storage with self-limiting current characteristic. The resistive random access memory can be prepared on a silicon substrate, the device unit is Metal-Insulator-Metal (MIM) capacitance structure, which uses a layered structure from upper to lower, where a middle functional layer uses parylene (parylene-C) with excellent resistive switching characteristic, a top electrode and a bottom electrode in the MIM structure preferably use W. The device are characterized by that, a parylene layer as the functional layer is formed by performing deposition multiple times, the multi-value storage function of the device is achieved according to different number of deposition times and the different deposition thickness each time.

In the conventional resistive random access memory, a resistive switching mechanism of the device caused by an active electrode mainly depends on a metal channel caused by the electrode diffusion, whereas the device of the present invention avoids the situation due to using of W electrodes at both sides, resulting in that the resistance switching is determined by the inherent defect in the parylene layer as the functional layer and the interface defect between the different parylene layers. For the electrode, the present invention preferably uses the inert electrode W, the inert here is mainly for no occurrence of diffusion into the parylene after the electrode ionization. Moreover, Pt electrode or TiN with electrical activity (ionization diffusion does not occur) etc. may be also used. The inert electrode is used mainly to avoid forming the conductive filament, because it is difficult to react completely in the formation/rupture of the metal filament, and it is possible that only one layer of the formed metal filament need be ruptured in the RESET process, thus only one low-resistance/high-resistance state is shown. Using the defect of parylene itself to conduct may effectively achieve the recovery of the high resistance.

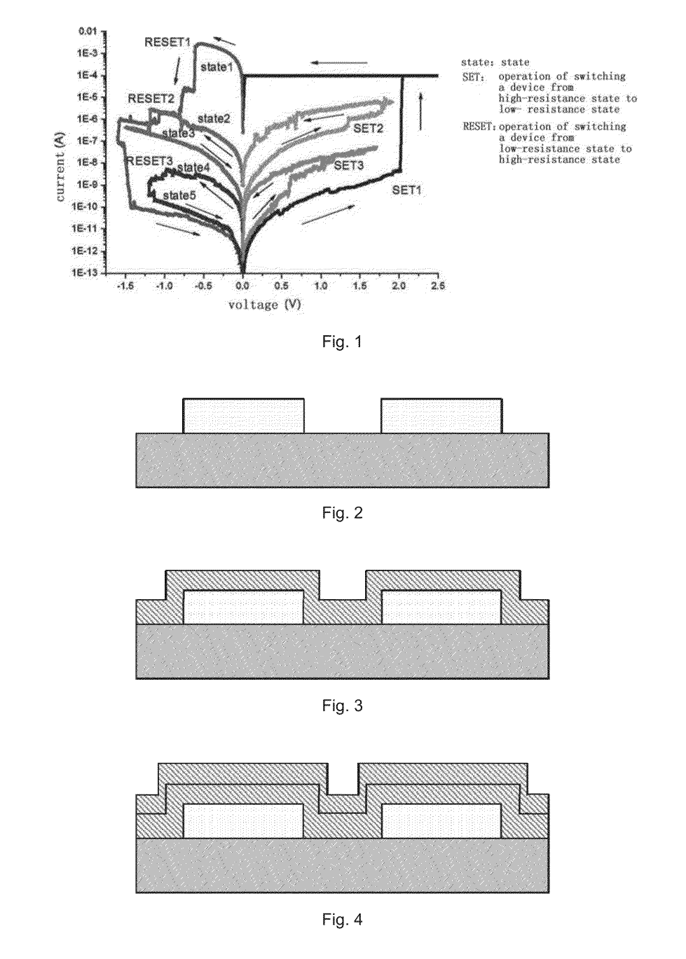

A current-voltage (I-V) characteristic curve in a resistive switching course of a resistive random access memory according to present invention is shown in FIG. 1. In FIG. 1, the SET and RESET processes of the respective resistance states in a structure of the three layers parylene (with a thickness 10 nm/10 nm/20 nm) are shown, the voltage scanning direction of the respective curves are shown by the arrow directions. It is seen that there are three sets of different SET and RESET processes, and three sets of switchable states there between (state1 and state5, state2 and state3, state4 and state5) in the device, wherein SET 1 and RESET 1 processes achieve a switch between state1 and state5; SET2 and RESET2 processes achieve a switch between state2 and state3; and SET3 and RESET3 processes achieve a switch between state4 and state5; the switches of the three set of states can be achieved by RESET processes, and it can be seen that the RESET1 curve can be divided into two large sudden stages, which are respectively correspond to the situations from state1 to state3 and from state1 to state5, therefore, the switching between the different states of the device can be controlled by adjusting the magnitude of an off voltage in the RESET1 course.

The description for a number of the layers of parylene, thickness of each layer and the number of values of the resistive random access memory are provided as follows:

Because the multi-value of the device is achieved by performing SET/RESET operation to the different layers of parylene one by one, thus turn-on/turn-off of each layer of parylene should generate correspondingly a separate set of low-resistance state and high-resistance state. According to the principle, if N layers of parylene are deposited, 2N different resistance states may be realized. However, because of different thicknesses of parylene, when the total thickness of the insulated layers of parylene is much larger than the total thickness of the conductive layers of parylene, the differences between the high-resistance state and the low resistance of the device in this case is not clear, as shown in FIG. 1, and it is difficult to distinguish between the high-resistance states obtained from state5 and state1 directly by RESET, thus only 2N-1, i.e., 5, states can be used. Because it is difficult to prepare a single layer of parylene to have a thickness below 10 nm, due to this limitation, the total thickness of the device becomes larger after the number of the layers of parylene becomes more, and the number of the states that can be distinguished effectively may be less than 2N, but at least N states could be achieved based on the fact that after at most half thickness of the layers of parylene are turned on, the resistance of the device is reduced significantly and the resistances differences of parylene turned on layer by layer become distinguishable. The thickness of each layer of parylene will influence the ratio of a pair of the low-resistance state/the high-resistance state corresponding to the turn-on/turn-off thereof, where the larger a single layer's thickness is, the greater the ratio of the corresponding low—resistance state/high—resistance state is. The present invention generally select the total thickness of the parylene to be between 40 nm and 80 nm, each layer's thickness is controlled to be between 10 nm and 20 nm.

The embodiments of the preparation method of the resistive random access memory of the present invention are provided as follows.

### EMBODIMENT 1

1) W with a thickness 500 nm, as a bottom electrode, is grown on a Si substrate by PVD process, and the bottom electrode is patterned by using the standard lithography, as shown in FIG. 2;

2) a first layer of Parylene-C with a thickness of 20 nm is grown by using Polymer CVD technology, as shown in FIG. 3; the deposition process is performed by using a parylene polymer CVD apparatus with the standard parameters, where a depositing speed is between 1 nm/min and 10 nm/min;

3) a second layer of Parylene-C with a thickness of 10 nm is grown by using Polymer CVD technology, as shown in FIG. 4; the deposition process is performed by using a parylene polymer CVD apparatus with the standard parameters, wherer a depositing speed is between 1 nm/min and 10 nm/min;

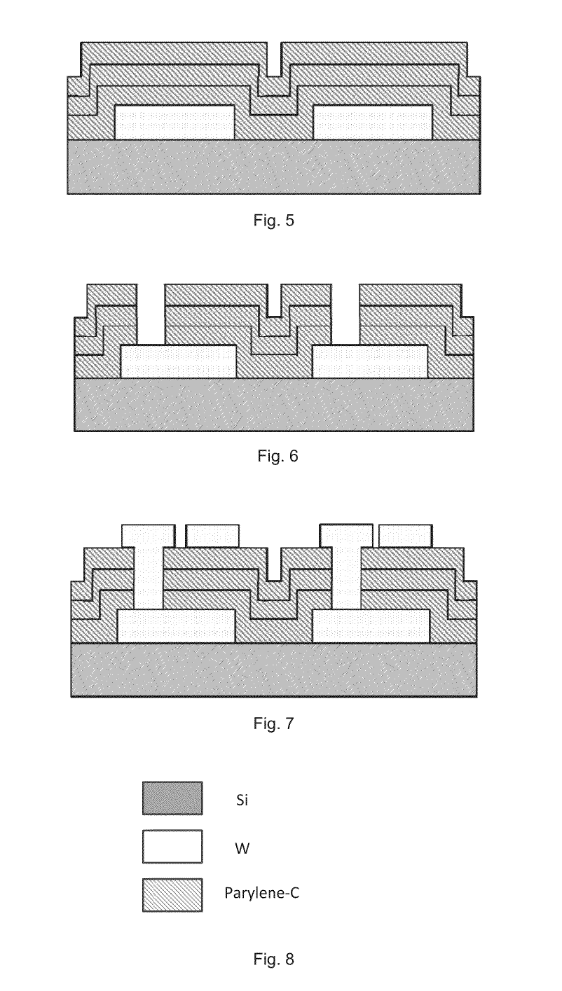

4) a third layer of Parylene-C with a thickness of 10 nm is grown by using Polymer CVD technology, as shown in FIG. 5; the deposition process is performed by using a parylene polymer CVD apparatus with the standard parameters, where a depositing speed is between 1 nm/min and 10 nm/min;

5) a via for leading out the bottom electrode is defined by photolithography and RIE etching, as shown in FIG. 6.

6) W with a thickness of 200 nm is sputtered by PVD process, a top electrode is defined by the conventional lithography and lift-off processes, meanwhile the bottom electrode is led out, as shown in FIG. 7.

### EMBODIMENT 2

1) W with a thickness of 500 nm as a bottom electrode is grown on Si substrate by using PVD process, and the bottom electrode is patterned by using the standard lithography;

2) a first layer of Parylene-D (or Parylene-N) with a thickness of 10 nm is grown by using Polymer CVD technology; the deposition process is performed by using a parylene polymer CVD apparatus with the standard parameters, where a depositing speed is between 1 nm/min and 10 nm/min;

3) a second layer of Parylene-N with a thickness of 20 nm is grown by using Polymer CVD technology; the deposition process is performed by using a parylene polymer CVD apparatus with the standard parameters, where a depositing speed is between 1 nm/min and 10 nm/min;

4) a third layer of Parylene-N with a thickness of 20 nm is grown by using Polymer CVD technology; the deposition process is performed by using a parylene polymer CVD apparatus with the standard parameters, where a depositing speed is between 1 nm/min and 10 nm/min;

5) a via for leading out the bottom electrode is defined by lithography and RIE etching.

6) W with a thickness of 500 nm is sputtered by PVD process, a top electrode is defined by the conventional lithography and lift-off processes, meanwhile the bottom electrode is led out.

In this embodiment 2, the thicknesses of multi-layer Parylene are 10/20/10 nm respectively, the layers with the SET/RESET course occurring are 10/20/10 nm respectively, and since the middle layer with 20 nm is thicker, the operation voltage of a middle state may be larger than in the embodiment 1, and it is better to distinguish between ranges of the operation voltages of the different layers of parylene and may achieve better device performance than in the embodiment 1.

The above embodiments are used to illustrate the technical solution of the present invention and are not intend to limit the present invention. Without departing from the scope of the present invention technical solution, modifications or equivalent substitute for the present technical solution may be made by those skilled in the art. The protection of the present invention is limited by the claims.

What is claimed is:

1. A multi-value nonvolatile organic resistive random access memory, comprising a top electrode, a bottom electrode and a middle functional layer located between the top electrode and the bottom electrode, the middle functional layer is at least two layers of parylene.

2. The multi-value nonvolatile organic resistive random access memory according to claim 1, wherein the top electrode and the bottom electrode each are an inert electrode.

3. The multi-value nonvolatile organic resistive random access memory according to claim 2, wherein the top electrode and the bottom electrode each are a W electrode, and have a thickness between 200 nm and 500 nm.

4. The multi-value nonvolatile organic resistive random access memory according to claim 1, wherein a total thickness of the parylene as the functional layer is between 40 nm and 80 nm, each layer of the parylene has a thickness between 10 nm and 20 nm.

5. The multi-value nonvolatile organic resistive random access memory according to claim 1, wherein a polymer of the parylene is parylene-C type, parylene-N type or parylene-D type.

6. A method for preparing the multi-value nonvolatile organic resistive random access memory according to claim 1, comprising the steps of:
1) growing a material for a bottom electrode using physical vapor deposition process, and patterning the bottom electrode using standard lithography technology;
2) growing sequentially multiple layer of parylene materials on the bottom electrode by polymer chemical vapor deposition;
3) defining a via for leading out the bottom electrode by lithography and etching;
4) growing a material for a top electrode on the parylene materials by using physical vapor deposition process, defining the top electrode by lithography and lift-off, and leading out the bottom electrode.

7. The method according to claim 6, wherein the top electrode and the bottom electrode each are an inert electrode, polymer of the parylene is parylene-C type, parylene-N type or parylene-D type.

8. The method according to claim 7, wherein the top electrode and the bottom electrode each are a W electrode, and have a thickness between 200 nm and 500 nm.

9. The method according to claim 6, wherein a total thickness of the parylene as the functional layer is between 40 nm and 80 nm, each layer of the parylene has a thickness between 10 nm and 20 nm, and there is a certain time, between depositings of each two layers of the parylene, for exposing at the atmosphere for surface oxidation.

10. The method according to claim 6, wherein in the step 2) of growing parylene materials by polymer chemical vapor deposition process, a depositing speed is between 1 nm/min and 10 nm/min.
